(19) United States
(12) Patent Application Publication
(10) Pub. No.: US 2009/0206856 A1
(43) Pub. Date: Aug. 20, 2009

(54) WAFER BURN-IN SYSTEM WITH PROBE COOLING

(75) Inventors: Jung-Hyun NAM, Seoul (KR); Ki-Sang KANG, Gyeonggi-do (KR); Gi-Bum KOO, Seoul (KR); Hoon-Jung KIM, Gyeonggi-do (KR); In-Seok HWANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/426,719

(22) Filed: Apr. 20, 2009

Related U.S. Application Data
(63) Continuation of application No. 11/326,026, filed on Jan. 4, 2006.

(30) Foreign Application Priority Data
Jan. 7, 2005 (KR) 2005-1682

(51) Int. Cl. G01R 31/02

(52) U.S. Cl. 324/754

(57) ABSTRACT

The present disclosure relates to a wafer burn-in system having a device cooling a probe card and thereby restraining heat accumulation in the probe card. The disclosed wafer burn-in system includes a probe station and a tester. The probe station includes a burn-in chamber, a probe head, and a wafer stage. The probe head has a probe card installed on the lower surface of the probe head. A cooling device restrains heat accumulation in the probe card, e.g., by generating airflow around the probe card. The wafer stage of the burn-in chamber fixes a wafer loaded on the upper surface of the wafer stage and elevates the wafer for contact with the probe card. The tester connects to the probe station through a general purpose interface bus (GPIB) to convey test signals to and from the probe head, and to control operation of the cooling device. The tester activates the cooling device, e.g., activates air blowers to generate airflow forcibly around the probe card and thereby restrain heat accumulation in the probe card during a burn-in process performed in the burn-in chamber.

### CROSS REFERENCE TO RELATED APPLICATION

This application is a Continuation of U.S. patent application Ser. No. 11/326,026, filed on Jan. 4, 2006, now pending, which claims priority under 35 U.S.C. § 119 from Korean Patent Application No. 2005-1682, filed on Jan. 7, 2005, in the Korean Intellectual Property Office, the entire contents of which are hereby incorporated by reference

### BACKGROUND OF THE INVENTION

1. Field of the Invention

The present invention relates to a wafer burn-in system using a probe card.

2. Detailed Description of the Related Art

A semiconductor chip is formed through a number of processes and typically is ultimately placed in a semiconductor package. A process of manufacturing a semiconductor chip may generally be divided into wafer forming, fabrication, and assembly processes. A plurality of semiconductor chips are formed in a common wafer. A wafer cutting (or singulating) process separates individual semiconductor chips.

Before the wafer cutting process, however, a screening process identifies viable semiconductor chips for submission to a subsequent assembly process. Electrical die sorting (EDS) for a semiconductor chip screens initial failure of the semiconductor chips. Recently, a wafer burn-in test has been performed to measure the reliability of the semiconductor chips by also applying thermal stress thereto, e.g., heating the wafer during the test.

A wafer test system comprises a tester and a probe station. A probe card mechanically contacts chip pads of a semiconductor chip in a wafer placed in the probe station. The probe card has very fine probe pins fixed on a card body. A signal generated by the tester transfers to the chip pads of the semiconductor chip through the probe pins individually installed on the probe card. The semiconductor chip is thereby checked or screened to determine viability.

The probe station, as used in the wafer burn-in test, further includes a burn-in chamber providing a high temperature test environment. Thus, contact between the probe card and wafer is made in the high temperature burn-in chamber.

However thermal deformation of the probe card may be caused by heat accumulation. Because the probe card is exposed repeatedly to high temperature and remains for a prolonged period in the burn-in chamber, heat accumulates within the probe card. The probe card uses plastic materials in various parts, such as the card body and fixing parts for the probe pins. As a result, thermal deformation of the probe card can occur after exposure to high temperature for extended periods in the burn-in chamber.

Unfortunately, thermal deformation results in displacement of the probe pins, desirably held in precise contact with the chip pads of the semiconductor chip, and may cause a loss of such contact, e.g., the probe pins may not correctly contact the chip pads of the semiconductor chip. In some cases, such thermal deformation can cause a lack of contact with the chip pads. As a result, a test signal may not be properly transferred or electrical short circuits may occur between the probe pins.

### SUMMARY OF THE INVENTION

Embodiments of the present invention restrain heat accumulation in a probe card. In certain embodiments, for example, generating airflow forcibly around the probe card in a burn-in chamber restrains heat accumulation during a burn-in process.

Disclosed embodiments of the present invention provide a wafer burn-in system comprising a probe station and a tester. The probe station includes a burn-in chamber, a probe head, and a wafer stage. The probe head has a probe card installed at its lower surface and has, for example, air blowers to restrain heat accumulation in the probe card by generating airflow around the probe card. The wafer stage, located within the burn-in chamber, fixes a wafer loaded on the wafer stage and elevates the wafer for probing by the probe card. The tester, connected to the probe station through, for example, a general purpose interface bus (GPIB), inputs and collects a test signal to/from the probe head, and controls operation of the air blowers. The tester activates the air blowers to generate airflow forcibly around the probe card and thereby restrains heat accumulation in the probe card while performing a burn-in process in the burn-in chamber.

The probe card, in accordance with certain embodiments of the present invention, includes a card body having a window. A probe pin module includes probe pins exposed through the window of the card body. A heat sink, located at the upper surface of the card body, holds the probe pin module to the card body.

The air blowers, in accordance with certain embodiments of the present invention, may be installed radially around the probe card to direct the air toward the probe card.

The air blowers may be installed above and outside the probe card and may be directed toward the probe card.

The air blowers may further be installed so as to drive the air toward the heat sink on the probe card.

Additionally, the tester, in accordance with embodiments of the present invention, activates the air blowers when the burn-in process starts and stops the air blowers through the general purpose interface bus when the burn-in process terminates.

Embodiments of the present invention propose application of heat to a wafer while removing heat from, e.g., cooling, a test probe applied to the wafer during a wafer burn-in procedure.

### BRIEF DESCRIPTION OF THE DRAWINGS

FIG. 1 is a schematic block diagram showing a wafer burn-in system with air blowers for cooling a probe card in accordance with an example embodiment of the present invention.

FIG. 2 is a plan view showing the air blowers installed around a probe card of FIG. 1.

FIG. 3 is a cross-sectional view taken along the line I-I of FIG. 2.

FIG. 4 is a cross-sectional view showing the probe card while probing a wafer in the wafer burn-in system of FIG. 1.

FIG. 5 is a process flow chart showing wafer burn-in steps including a step of cooling the probe card in the wafer burn-in system of FIG. 1.

### DETAILED DESCRIPTION

Hereinafter, example embodiments of the present invention will be described in more detail with reference to the accompanying drawings.

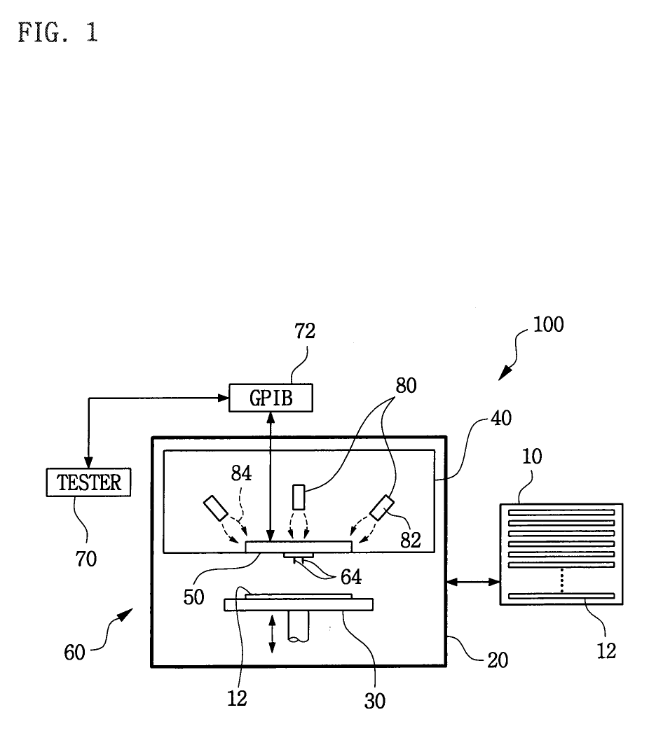

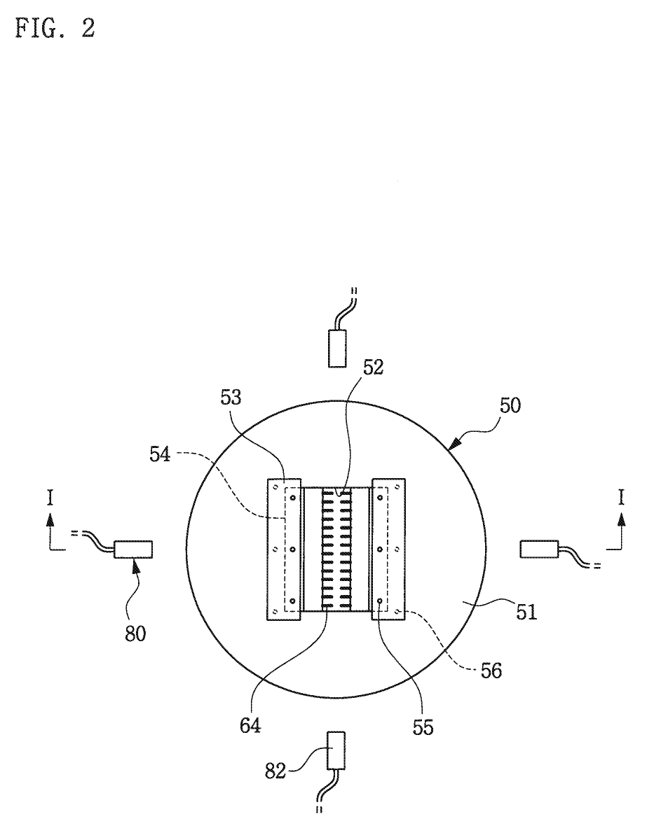

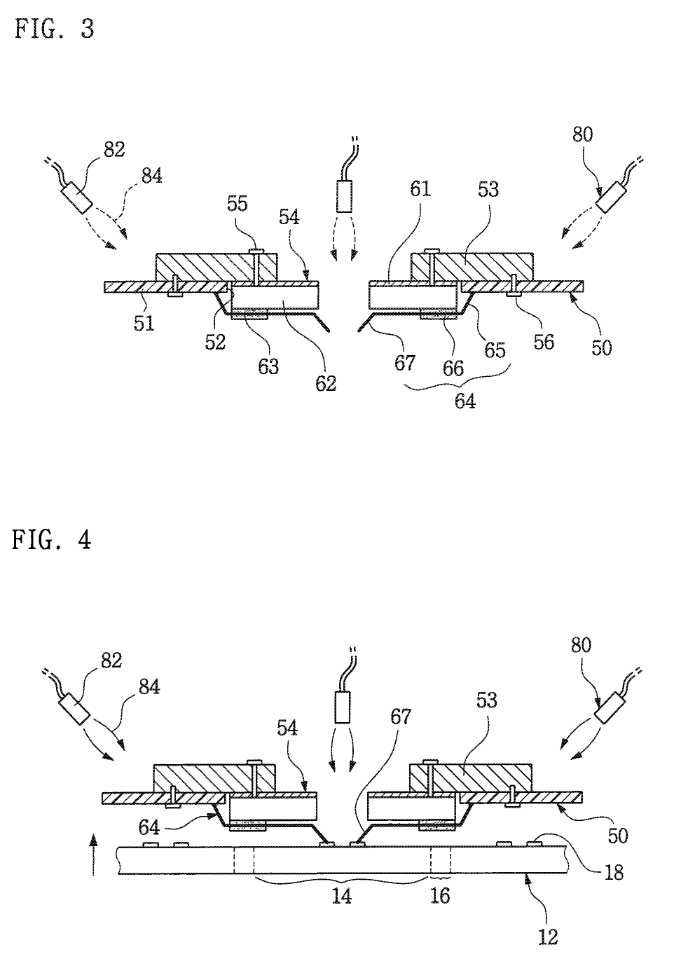

FIG. 1 is a schematic block diagram showing a wafer burn-in system 100 with air blowers 80 for cooling a probe card 50 in accordance with an example embodiment of the present invention. FIG. 2 is a plan view showing the air blowers 80 installed around the probe card 50 of FIG. 1. FIG. 3 is a cross-sectional view taken along the line I-I of FIG. 2. FIG. 4 is a cross-sectional view showing the probe card 50 probing a wafer 12 in the wafer burn-in system 100 of FIG. 1.

Referring to FIGS. 1 to 4, the wafer burn-in system 100 in accordance with the example embodiment of the present invention comprises a tester 70 and a probe station 60. The tester 70 and probe station 60 are interconnected for signal exchange by a general purpose interface bus (GPIB) 72. Signals transferred between tester 70 and probe station 60 accomplish tests relative to a wafer 12 held within station 60.

The probe station 60 includes a burn-in chamber 20 for conducting a burn-in process. A probe head 40 resides within the burn-in chamber 20 and includes a probe card 50 installed on the lower surface of the probe head 40. A wafer stage 30 also installed within the burn-in chamber 20 holds a wafer 12 on its upper surface whereby wafer stage 30 elevates the wafer 12 for probing, e.g., testing, by the probe card 50.

A wafer cassette 10, installed proximate to the burn-in chamber 20, supplies the wafer 12 to the wafer stage 30 and receives the wafer 12 after testing. As may be appreciated, the cassette 10 may be employed to deliver a series of wafers 12 to the chamber 20 for sequential testing. A transfer arm (not shown) may be used to load and unload the wafer 12 between the wafer stage 30 and wafer cassette 10.

The wafer burn-in system in accordance with the present invention incorporates air blowers 80 to manage thermal deformation of the probe card 50, e.g., due to heat accumulation in the burn-in process. More particularly, the heat accumulation in the probe card 50 is managed, e.g., reduced or limited, by generating airflow around the probe card 50. The tester 70, as connected through the general purpose interface bus 72, activates and controls the air blowers 80. In this manner, tester 70 reduces undesirable heat accumulation in the probe card 50 by generating and directing airflow forcibly around the probe card 50 during the burn-in process performed in the burn-in chamber 20.

Accordingly, the wafer burn-in system 100 in accordance with the example embodiment of the present invention addresses potential thermal deformation of the probe card 50. Because the air blowers 80 forcibly generate airflow around the probe card 50 and heat accumulation in the probe card 50 is reduced, thermal deformation is reduced or eliminated.

Air blowers 80 may take as a source air from outside chamber 20 or may remove heat energy from air 84 prior to application to the probe head 40. In this manner, a temperature differential between ambient chamber 20 conditions and air 84 may be established to more effectively cool the probe head 40.

The structure of the air blowers 80 as installed around the probe card 50 in this particular embodiment of the present invention will be described in more detail as follows. The probe card 50 includes a card body 51 having a window 52, e.g., generally at its center, formed between the heat sinks 53. A probe pin module 54 is exposed through the window 52 of the card body 51. Probe pins 64 included in the probe pin module 54 are exposed downward, in the view of FIG. 3, from the card body 51 and extend below the window 52.

The probe pin module 54 is equipped with a ceramic block 62 of a predetermined length, a reinforcing material 61 on the upper surface of the ceramic block 62, and probe pins 64. Probe pins 64 are arranged on the lower surface of the ceramic block 62 in the lengthwise direction of the ceramic block 62 and fixed by epoxy resin 63. The probe pins 64 may be contact pins made of tungsten material and include a joining part 65 electrically connecting to the card body 51, a fixing part 66 connected to the joining part 65 and fixed by the epoxy resin 63 formed on the lower surface of the ceramic block 62, and a contact part 67 connected to the fixing part 66 and protruding downward for contact with a chip pad 18 of a semiconductor chip 14 on a wafer 12. The joining part 65 may be attached to the lower surface of the card body 51 by, for example, soldering. The contact part 67 is bent away from the lower surface of the card body 51 in such manner that the contact part 67, having a specific elasticity, is in suitable electrical contact with the chip pad 18 of the semiconductor chip 14.

The probe pin module 54 inserts through the window 52 of the card body 51 and couples to the card body 51 by way of the heat sink 53. In more detail, the heat sink 53 is fixed at one side on the upper surface of the probe pin module 54 by first fixing pins 55. The heat sink 53 is also fixed to the card body 51 by second fixing pins 56. The probe pin module 54 is thereby exposed through the window 52. The first fixing pins 55 are inserted and fixed to the reinforcing material 61 located on the upper surface of the probe pin module 54, piercing the heat sink 53 from its upper surface. The second fixing pins 56 are inserted and fixed to the heat sink 53, piercing the card body 51 from its lower surface.

Heat generated from the probe pin module 54 and card body 51 is primarily dissipated through the heat sink 53. The heat sink 53 may be a metal plate having suitable thermal conductivity, such as a copper or an aluminum plate.

The air blowers 80 are installed radially, for example, around the probe card 50, and include injection nozzles 82 directing the air 84 toward the probe card 50. Preferably, the air blowers 80 are installed above and outside the probe card 50 but directed toward the probe card 50 to inject or drive the air 84 uniformly toward the probe card 50. More preferably, the air blowers 80 are positioned to drive the air 84 toward the heat sink 53 as installed on the upper surface of the card body 51. According to this particular example embodiment of the present invention disclosed herein, the injection nozzles 82 are installed at four positions. It will be understood, however, that the particular number and positioning of the air blowers 80 may vary while still managing heat accumulation relative to the probe card.

Accordingly, the air 84 as provided by the air blowers 80 effectively cools the probe card 50. Because the probe card 50 itself is cooled and because heat transferred to the heat sink 53 is further dissipated to the outside of the probe card 50, heat accumulation relative to the probe card 50 is restrained, e.g., limited, in such manner as to reduce or eliminate undesirable thermal deformation of the probe card 50.

According to one particular method of operation, the tester 70 activates the air blowers 80 through the general purpose interface bus 72 to restrain heat accumulation in the probe card 50 when the burn-in process starts, and stops the air blowers 80 through the general purpose interface bus 72 when the burn-in process terminates. Under such example method, the air blowers 80 may be activated and de-activated for each wafer 12 brought into chamber 20. It will be understood, however, that other control schemes, e.g., not necessarily tied to wafer 12 movements, may be used to manage heat accumulation in the probe card 50.

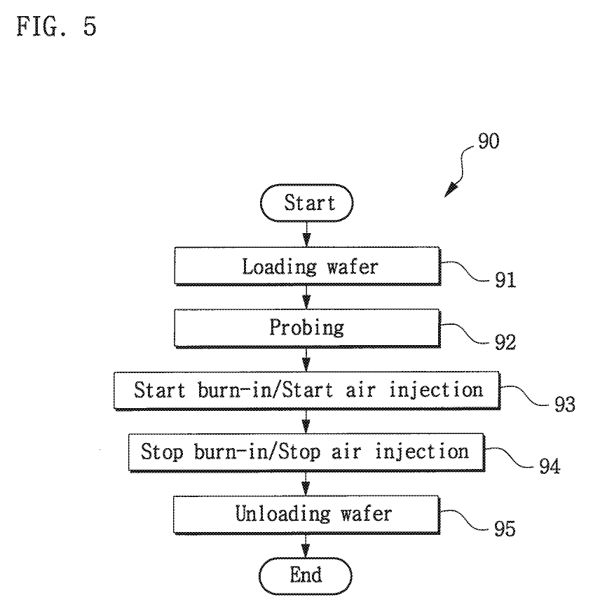

A wafer burn-in process 90 including cooling operation for a probe card 50, using a wafer burn-in system 100 in accordance with the example embodiment of the present invention, will be described referring to FIGS. 1 to 5. FIG. 5 is a process flow chart showing a wafer burn-in process 90 including cooling operation for the probe card 50 in the wafer burn-in system 100 of FIG. 1.

The probe card 50 is installed such that the probe pins 64 face downward from the probe head 40, then a wafer loading step is performed (91 of FIG. 5). A wafer 12 is transferred from a wafer cassette 10 and loaded on the top of a wafer stage 30 by a transfer arm (not shown) while a burn-in chamber 20 is open. The wafer stage 30 holds the wafer 12 by, for example, vacuum suction.

When the wafer loading is completed, the burn-in chamber 20 is closed, and a suitable temperature condition, e.g., as required for the burn-in process, is established by heating.

Subsequently, as shown in FIG. 4, a probing step is performed (92 of FIG. 5). The wafer 12 is then tested by the probe card 50, e.g., once the wafer stage 30 is elevated to the probe card 50. The elevated wafer 12 presses against the probe card 50 with a specific pressure. More particularly, contact parts 67 each mechanically contact a chip pad 18 of a semiconductor chip 14 with a specific contact pressure. The reference number 16 in FIG. 4 indicates a chip cutting area separating individual semiconductor chips 14 on the wafer 12. In FIG. 4, illustration of a probe head and a wafer stage is omitted to show in more detail the state of the wafer 12 being tested by the probe card 50.

Subsequently, a burn-in step and an air injection step are performed simultaneously (93 of FIG. 5). A tester 70 inputs a test signal to the probe card 50 through a general purpose interface bus 72. The semiconductor chip 14 is thereby tested to determine if it passes or fails according to a return output signal, e.g., corresponding to the test signal input through the general purpose interface bus 72. Additionally, the tester 70 activates air blowers 80 through the general purpose interface bus 72 to restrain or limit heat accumulation in the probe card 50 while the burn-in process is performed.

Heat generated from a probe pin module 54 is primarily dissipated to the outside of the probe card 50 through the heat sink 53. Heat transferred to the heat sink 53 is forcibly dissipated to the outside of the probe card 50 by the air 84 as provided by the air blowers 80. As a result, undesirable heat accumulation in the probe card 50 is limited.

Subsequently, when the burn-in step terminates, a step of stopping air injection is performed (94 of FIG. 5). The tester 70 stops operation of the air blowers 80 through the general purpose interface bus 72 when the burn-in step terminates.

Lastly, a wafer unloading step is performed (95 of FIG. 5). The elevated wafer stage 30 descends and returns to its initial position. After the burn-in chamber 20 is opened, the wafer 12 is unloaded from the wafer stage 30 to the wafer cassette 10 by the transfer arm (not shown).

The same process as described above is repeated, and the burn-in process is performed sequentially for the wafers 12 stacked in the wafer cassette 10.

Certain embodiments of the present invention restrain heat accumulation in a probe card by installing air blowers around a probe card and directing air toward the probe card, e.g., by activating the air blowers according to a control signal from a tester through a general purpose interface bus.

Accordingly, high reliability in the contact between probe pins and chip pads of a semiconductor chip is obtained. Problems in a test due to thermal displacement of the probe pins may be decreased because heat accumulation in the probe card is restrained during the burn-in process.

Although the example embodiments and drawings of the present invention have been disclosed for illustrative purposes, those skilled in the art will appreciate that various substitutions, modifications, and changes are possible, without departing from the scope and spirit of the invention as disclosed in the accompanying claims. Therefore, this invention should not be construed as limited to the embodiments set forth herein or to the accompanying drawings.

What is claimed is:

1. A method, comprising:
providing a probe station, the probe station comprising:
a burn-in chamber;
a probe head within the burn-in chamber, the probe head comprising:
a probe card having a first surface and a second surface; and
at least one air blower disposed above the first surface of the probe card; and
a wafer stage within the burn-in chamber;
providing a tester, wherein the tester is connected to the probe station via a general purpose interface bus, and wherein the tester is operable to:
send a test signal to the probe head through the general purpose interface bus; and
control operation of the at least one air blower through the general purpose interface bus;
loading a wafer into the burn-in chamber, wherein the wafer is loaded on the wafer stage such that the wafer faces the second surface of the probe card;
probing the wafer with the probe card;
performing a burn-in test of the wafer;
performing an air blowing onto the first surface of the probe card, wherein the tester activates the at least one air blower through the general purpose interface bus;
stopping the burn-in test of the wafer; and
unloading the wafer from the burn-in chamber.

2. The method of claim 1, further comprising:
heating an inside portion of the burn-in chamber above an ambient temperature prior to performing the burn-in test of the wafer, wherein heating the inside portion of the burn-in chamber occurs after loading the wafer and before probing the wafer, and wherein the burn-in chamber is configured to heat the wafer above the ambient temperature.

3. The method of claim 1, wherein probing the wafer with the probe card comprises elevating the wafer stage and the wafer on the wafer stage to the probe card.

4. The method of claim 3, wherein the probe card comprises a plurality of probe pins on the second surface of the probe card, and wherein probing the wafer with the probe card comprises pressing the wafer against the probe card with a predetermined pressure such that the wafer contacts the plurality of probe pins.

5. The method of claim 1, wherein the steps of performing the burn-in test of the wafer and performing the air blowing are performed simultaneously.

6. The method of claim 1, wherein the at least one air blower is disposed radially around the probe card.

7. The method of claim 1, wherein the at least one air blower is disposed outside the probe card.

8. The method of claim 1, wherein the probe card further comprises a heat sink coupled with the probe pin.

9. The method of claim 8, wherein the air blowing from the at least one air blower is directed toward the heat sink.

10. The method of claim 1, wherein stopping the burn-in test of the wafer comprises stopping the air blowing by deactivating the at least one air blower through by the tester through general purpose interface bus.
